(19) United States
(12) Patent Application Publication
(10) Pub. No.: US 2026/0146325 A1
(43) Pub. Date: May 28, 2026

(54) VAPOR-PHASE TRANSPORT OF NON-VOLATILE METAL HALIDE COMPOUND PRECURSORS

(71) Applicant: ASM IP Holding B.V., Almere (NL)

(72) Inventors: Patricio Eduardo Romero, Boutersem (BE); Charles Dezelah, Helsinki (FI); Balaji Kannan, Phoenix, AZ (US)

(21) Appl. No.: 19/398,545

(22) Filed: Nov. 24, 2025

Related U.S. Application Data
(60) Provisional application No. 63/726,100, filed on Nov. 27, 2024.

(51) Int. Cl. C23C 16/455

(52) U.S. Cl. CPC C23C 16/45553

(57) ABSTRACT

The current disclosure relates to a composition for depositing metals on a substrate. The composition comprises a chemical precursor comprising a metal halide compound and a carrier agent for transporting said chemical precursor in a vapor phase, the carrier agent comprising a group 13 halide having, under a pressure within the precursor vessel, a volatilization temperature below a volatilization temperature of the metal halide compound. The disclosure further relates to a precursor vessel comprising the composition, and to a chemical vapor deposition system and method for depositing metals using the composition.

### CROSS-REFERENCE TO RELATED APPLICATION(S)

This Application claims the benefit of U.S. Provisional Application 63/726,100 filed on Nov. 27, 2024, the entire contents of which is incorporated herein by reference.

### TECHNICAL FIELD OF THE INVENTION

The present invention relates to the field of chemical vapor deposition, and more specifically to vapor-phase transport of metal halide compound precursors for chemical vapor deposition.

### BACKGROUND OF THE INVENTION

Deposition techniques such as chemical vapor deposition (CVD), and in particular atomic layer deposition (ALD), are essential techniques in the fabrication of semiconductor devices, enabling the controlled deposition of thin films at the atomic level. These processes rely on the delivery of chemical precursors in the vapor phase to react on substrate surfaces, forming materials with precise compositions and properties required for advanced electronic applications.

Metal-organic precursors are commonly used in CVD due to their volatility and thermal stability, which facilitate efficient vapor transport and deposition. These precursors consist of metal centers coordinated to organic ligands, allowing them to vaporize at relatively low temperatures. However, the incorporation of carbon-containing ligands can introduce impurities such as carbon, nitrogen, or oxygen into the deposited films. Such impurities may adversely affect the electrical, optical, or structural properties of the thin films, posing challenges for achieving the desired material performance.

In contrast, inorganic metal halides, composed solely of metal and halogen elements, offer the advantage of being free from potential contaminants associated with organic ligands. Volatile halides such as titanium tetrachloride (TiCl₄), tantalum pentachloride (TaCl₅), molybdenum pentachloride (MoCl₅), and silicon tetrachloride (SiCl₄) have been successfully utilized as precursors in CVD processes. These compounds are commodity chemicals that do not require complex synthesis, making them economically favorable for large-scale manufacturing.

Despite these benefits, the applicability of inorganic metal halides is limited by the volatility of a wide range of inorganic metal halides. A significant number of metals, including cobalt, ruthenium, manganese, nickel, scandium, yttrium, and the lanthanide series elements, form halides that are non-volatile under typical processing conditions. These metal halides often exist as crystalline solids with strong intermolecular forces, requiring high thermal energy to vaporize. The temperatures needed to achieve sufficient vapor pressures for these materials can be impractically high, potentially leading to thermal decomposition or unwanted reactions that compromise film quality.

The inability to effectively vaporize and transport non-volatile metal halides poses a barrier to incorporating a wider range of metals into thin-film technologies. As the semiconductor industry advances, there is an increasing demand for diverse materials with specialized functionalities. The development of processes that can deliver these metals in vapor form is crucial for expanding the capabilities of CVD techniques, enabling the production of next-generation devices with improved performance and novel features.

The search for methods to facilitate the vapor transport of these materials without introducing impurities or compromising the integrity of the deposited films is ongoing. There is a continuing need for advancements in the field to address at least some of these challenges.

### SUMMARY OF THE INVENTION

It is an objective of embodiments of the present invention to enable vapor transport of metal halide compounds.

The above objective is accomplished by methods and apparatus according to the present invention.

It is an advantage of embodiments of the present invention that normally non-volatile metal halide compounds may be transported in the vapor phase. It is an advantage of embodiments of the present invention that metal halide compounds that do not naturally furnish volatile forms can be utilized effectively in chemical vapor deposition processes, such as atomic layer deposition processes.

It is an advantage of embodiments of the present invention that a wide range of metals may be used for deposition without introducing potential contaminants, typically resulting from organic ligands.

It is an advantage of embodiments of the present invention that this method enables more economical and efficient deposition of thin films for semiconductor manufacturing by reducing the need for elaborate ligand designs to achieve volatility.

In a first aspect, the present invention relates to a precursor vessel comprising:
a. a chemical precursor comprising a metal halide compound, and
b. a carrier agent for transporting said chemical precursor in a vapor phase, the carrier agent comprising a group 13 halide having, under a pressure within the precursor vessel, a volatilization temperature below a volatilization temperature of the metal halide compound,

wherein the precursor vessel is configured to supply a vapor comprising the chemical precursor and the carrier agent to a reaction chamber of a chemical vapor deposition system.

In a second aspect, the present invention relates to a method for chemical vapor depositing a material comprising a metal on a substrate, the method comprising:
a. providing the substrate in a reaction chamber, and then
b. providing, from a first source, into the reaction chamber, a vapor-phase composition comprising a multinuclear complex comprising:
   i. a chemical precursor comprising a halide compound of the metal, the metal halide compound having a volatilization temperature, under a pressure at a location along a flow path of the composition from the first source to the reaction chamber, above a temperature at said location, coordinated with
   ii. a carrier agent for transporting said metal halide compound in the vapor phase, the carrier agent comprising a group 13 halide having a volatilization temperature, under said pressure, below said temperature,
thereby forming a thin film comprising the metal on a portion of a surface of the substrate.

In a third aspect, the present invention relates to a system for chemical vapor depositing a material comprising a metal, the system comprising:
a. a reaction chamber for receiving the substrate,
b. a first source, coupled to the reaction chamber via a first valve, for providing a vapor-phase composition comprising a multinuclear complex comprising:
   (i). a chemical precursor comprising a halide compound of the metal, coordinated with
   (ii). a carrier agent for transporting said chemical precursor in the vapor phase, the carrier agent comprising a group 13 halide, and
c. a controller operably connected to the first valve, wherein the controller is configured and programmed to open the first valve to provide a flow of the composition into the reaction chamber and to close the first valve to cease the flow of the composition into the reaction chamber,

wherein the system is configured for, when said first valve is open, providing a temperature and a pressure at a location along a flow path of the composition from the first source to the reaction chamber, wherein a volatilization temperature, under said pressure, of the metal halide compound is above said temperature, and a volatilization temperature, under said pressure, of the group 13 halide is below said temperature.

In a fourth aspect, the present invention relates to a composition configured for depositing a thin film by chemical vapor deposition, preferably by atomic layer deposition, the composition comprising:
a. a chemical precursor comprising a metal halide compound, and
b. a carrier agent for transporting said chemical precursor in a vapor phase, the carrier agent comprising a group 13 halide and having, under a pressure within a range of from 10 to 1000 Pa, a volatilization temperature below a volatilization temperature of the metal halide compound.

In a fifth aspect, the present invention relates to a precursor vessel comprising:
a housing defining an interior volume of the precursor vessel,
an inlet conduit seated in the housing and in fluid communication with the interior volume of the precursor vessel, the inlet conduit comprising at least one valve positioned thereon,
an outlet conduit seated in the housing and in fluid communication with the interior volume of the precursor vessel, the outlet conduit comprising at least one valve positioned thereon, and
a metal halide compound impounded within the interior volume of the precursor vessel, wherein the metal halide compound comprises:
   (i) a metal selected from the group consisting of cobalt, ruthenium, manganese, nickel, a group 3 metal, and a metal from the lanthanide series, and
   (ii) one or more halogen atoms.

Particular and preferred aspects of the invention are set out in the accompanying independent and dependent claims. Features from the dependent claims may be combined with features of the independent claims and with features of other dependent claims as appropriate and not merely as explicitly set out in the claims.

Although there has been constant improvement, change and evolution of devices in this field, the present concepts are believed to represent substantial new and novel improvements, including departures from prior practices, resulting in the provision of more efficient, stable and reliable devices of this nature.

The above and other characteristics, features and advantages of the present invention will become apparent from the following detailed description, taken in conjunction with the accompanying drawings, which illustrate, by way of example, the principles of the invention. This description is given for the sake of example only, without limiting the scope of the invention. The reference figures quoted below refer to the attached drawings.

### BRIEF DESCRIPTION OF THE DRAWINGS

FIG. 1 is a schematic representation of a system in accordance with embodiments of the present invention.

FIG. 2 is a schematic representation of a reaction chamber of the system after deposition of a thin film comprising a metal halide compound and a group 13 halide on a substrate, in accordance with embodiments of the present invention.

FIG. 3 is a schematic representation of the reaction chamber of the system, wherein the group 13 halide is selectively removed from the thin film, in accordance with embodiments of the present invention.

FIG. 4 is a schematic representation of the reaction chamber of the system, after removal of the group 13 halide, in accordance with embodiments of the present invention.

FIG. 5 is a schematic representation of a precursor vessel in accordance with embodiments of the present invention comprising a separate chamber for the metal halide compound and the group 13 halide, in accordance with embodiments of the present invention.

FIG. 6 schematically shows coordination of a carrier agent aluminium chloride to a metal chloride.

In the different figures, the same reference signs refer to the same or analogous elements.

### DESCRIPTION OF ILLUSTRATIVE EMBODIMENTS

The present invention will be described with respect to particular embodiments and with reference to certain drawings but the invention is not limited thereto but only by the claims. The drawings described are only schematic and are non-limiting. In the drawings, the size of some of the elements may be exaggerated and not drawn on scale for illustrative purposes. The dimensions and the relative dimensions do not correspond to actual reductions to practice of the invention.

Furthermore, the terms first, second, third and the like in the description and in the claims, are used for distinguishing between similar elements and not necessarily for describing a sequence, either temporally, spatially, in ranking or in any other manner. It is to be understood that the terms so used are interchangeable under appropriate circumstances and that the embodiments of the invention described herein are capable of operation in other sequences than described or illustrated herein.

Moreover, the terms top, bottom, over, under and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

It is to be noticed that the term “comprising” should not be interpreted as being restricted to the means listed thereafter; it does not exclude other elements or steps. It is thus to be interpreted as specifying the presence of the stated features, integers, steps or components as referred to, but does not preclude the presence or addition of one or more other features, integers, steps or components, or groups thereof. The term “comprising” therefore covers the situation where only the stated features are present and the situation where these features and one or more other features are present. The word “comprising” according to the invention therefore also includes as one embodiment that no further components are present. Thus, the scope of the expression “a device comprising means A and B” should not be interpreted as being limited to devices consisting only of components A and B. It means that with respect to the present invention, the only relevant components of the device are A and B. In some embodiments, the term “comprising” includes “consisting.”

Similarly, it is to be noticed that the term “coupled” should not be interpreted as being restricted to direct connections only. The terms “coupled” and “connected”, along with their derivatives, may be used. It should be understood that these terms are not intended as synonyms for each other. Thus, the scope of the expression “a device A coupled to a device B” should not be limited to devices or systems wherein an output of device A is directly connected to an input of device B. It means that there exists a path between an output of A and an input of B which may be a path including other devices or means. “Coupled” may mean that two or more elements are either in direct physical or electrical contact, or that two or more elements are not in direct contact with each other but yet still co-operate or interact with each other.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment, but may. Furthermore, the particular features, structures or characteristics may be combined in any suitable manner, as would be apparent to one of ordinary skill in the art from this disclosure, in one or more embodiments.

Similarly, it should be appreciated that in the description of exemplary embodiments of the invention, various features of the invention are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the detailed description are hereby expressly incorporated into this detailed description, with each claim standing on its own as a separate embodiment of this invention.

Furthermore, while some embodiments described herein include some but not other features included in other embodiments, combinations of features of different embodiments are meant to be within the scope of the invention, and form different embodiments, as would be understood by those in the art. For example, in the following claims, any of the claimed embodiments can be used in any combination.

Furthermore, some of the embodiments are described herein as a method or combination of elements of a method that can be implemented by a processor of a computer system or by other means of carrying out the function. Thus, a processor with the necessary instructions for carrying out such a method or element of a method forms a means for carrying out the method or element of a method. Furthermore, an element described herein of an apparatus embodiment is an example of a means for carrying out the function performed by the element for the purpose of carrying out the invention.

In the description provided herein, numerous specific details are set forth. However, it is understood that embodiments of the invention may be practiced without these specific details. In other instances, well-known methods, structures and techniques have not been shown in detail in order not to obscure an understanding of this description.

The following terms are provided solely to aid in the understanding of the invention.

As used herein, and unless otherwise specified, the term “volatilization temperature” of a substance refers to the temperature at which the substance (that is, the pure substance, so not in a mixture but in its pure form) transitions from a condensed phase (solid or liquid) to a vapor phase, under a specified pressure. The volatilization temperature may be a sublimation temperature, a boiling temperature or an evaporation temperature. The volatilization temperature is dependent on pressure, as also indicated elsewhere in the description, and unless otherwise specified, the volatilization temperature of a material refers to that at the location of the material, i.e., under a pressure of an environment of the material.

As used herein, and unless otherwise specified, the term “substantially” as applied to a composition, a method, or a system, generally refers to a proportion of a value, a property, a characteristic, or the like, or conversely a lack thereof, that is at least about 70%, at least about 80%, at least about 90%, at least about 95%, at least about 97%, at least about 98%, at least about 99%, at least about 99.5%, at least about 99.9%, or more, or any proportion between about 70% and about 100%. In some embodiments, the term “substantially” means a proportion of about 90%, about 95%, about 97%, about 98%, about 99%, about 99.5%, or about 99.9%.

As used herein, and unless otherwise specified, the term “chemical vapor deposition” means a process wherein material is deposited on a substrate from a vapor phase, and wherein a reaction takes place between the material and the substrate. Said reaction may occur directly with the material still in the vapor phase, but this is not essential and instead, first, non-reactive deposition, such as condensation or physical adsorption, may occur without initially chemically altering the material, before said reaction takes place.

As used herein, and unless otherwise specified, the term “layer” and/or “film” can refer to any continuous or non-continuous material, such as material deposited by the methods disclosed herein. For example, layer and/or film can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous. In some embodiments, a layer according to the current disclosure is substantially continuous.

As used herein, a “substrate” refers to an underlying material or materials that may be used to form, or upon which, a device, a circuit, a material, or a material layer may be formed. The substrate may be continuous or non-continuous; rigid or flexible; solid or porous; and combinations thereof. The substrate may be in any form, such as, for example, a powder, a sheet, a plate, or a workpiece. Substrates in the form of a sheet may extend beyond the bounds of a reaction space or a process/reaction chamber where a deposition process occurs and, in some cases, move through the chamber such that the process continues until the end of the substrate is reached. Substrates in the form of a plate may include wafers in various shapes and sizes. Substrates may be made from semiconductor materials, including, for example, Mo, Mo germanium, Mo oxide, gallium arsenide, gallium nitride, and Mo carbide. A substrate can include one or more layers overlying a bulk material, for example the substrate may include nitrides, for example TiN, oxides, insulating materials, dielectric materials, conductive materials, metals, such as tungsten, ruthenium, Group 6 metal, cobalt, aluminum, or copper, or other metallic materials, crystalline materials, epitaxial, heteroepitaxial, and/or single crystal materials. The substrate can include various topologies, such as, for example, gaps, recesses, lines, trenches, vias, holes, or spaces between elevated portions, such as fins, and the like formed within or on at least a portion of a layer of the substrate.

The invention will now be described by a detailed description of several embodiments of the invention. It is clear that other embodiments of the invention can be configured according to the knowledge of persons skilled in the art without departing from the technical teaching of the invention, the invention being limited only by the terms of the appended claims.

In a first aspect, the present invention relates to a precursor vessel comprising:
a. a chemical precursor comprising a metal halide compound, and
b. a carrier agent for transporting said chemical precursor in a vapor phase, the carrier agent comprising a group 13 halide having, under a pressure within the precursor vessel, a volatilization temperature that is below a volatilization temperature of the metal halide compound,

wherein the precursor vessel is configured to supply a vapor comprising the chemical precursor and the carrier agent to a reaction chamber of a chemical vapor deposition system, preferably to a reaction chamber of a semiconductor processing apparatus. The reaction chamber of the chemical vapor deposition system, i.e., the chemical vapor deposition system reaction chamber, may be an atomic layer deposition system reaction chamber.

A wide range of metal halide compounds have a volatilization temperature that is too high for the metal halide compounds to be useable in chemical vapor deposition techniques, such as atomic layer deposition, under typical processing conditions. In some embodiments, the metal halide compound may have a volatilization temperature of at least 250° C., at least 300° C., at least 400° C., or even at least 500° C., under said pressure within the precursor vessel.

The present invention allows for the transport the metal halide compounds into the vapor phase, thereby allowing normally non-volatile metal halide compounds to be used in chemical vapor deposition processes. The carrier agent has a lower volatilization temperature and may, therefore, be in the vapor phase at lower temperatures than the chemical precursor. The volatilization temperature of the group 13 halide may be at least 20° C. lower, preferably at least 50° C. lower, more preferably at least 100° C. lower, even more preferably at least 200° C. lower, than the volatilization temperature of said metal halide compound, under said pressure.

If the group 13 halide is in the vapor phase, it may interact with the metal halide compound, which is typically condensed, to transport the latter into the vapor-phase as well. In particular, exposure of the metal halide compound to a vapor of the carrier agent may generate discrete vapor-phase multinuclear complexes (as schematically depicted in FIG. 6 for an example of three molecules of the carrier agent aluminium trichloride coordinating to a metal (M) trichloride). The metal halide compound may then, contained in said multinuclear complex, be transported in the vapor phase, even if the temperature of the environment is below the volatilization temperature of the metal halide compound.

The metal halide compound and the group 13 halide may be present in the precursor vessel coordinated with each other, forming said multinuclear complex. The multinuclear complex may comprise one or more molecules of the metal halide compound coordinated to one or more molecules of the group 13 halide. The multinuclear complex may generally be described by the following chemical formula: (MXₓ)_{w}(M′X′_{y})_{z}, with M the metal of the metal halide compound, each X independently a halogen, and optional oxygen or nitrogen, atom of the metal halide compound, the M′ a group 13 element and each X′ independently a halogen, and optional oxygen or nitrogen, atom of the group 13 halide. Subscript x may be from 1 to 6, such as from 3 to 5. Subscript y may be 1 or 3, but is typically 3. Subscript w is typically 1, although a value larger than 1 is not strictly excluded. Subscript z may be 2 or 3, or equal to x, although this is not strictly required. The multinuclear complex may alternatively be described, for example if x=z and w=1, by (M)(XM′X′_{y})_{z}, which is, for the purpose of the present invention, considered to be equivalent to (MXₓ)_{w}(M′X′_{y})_{z}.

In embodiments, the metal halide compound is a metal atom bonded to one or more halogen atoms. In embodiments, the metal halide compound may be a metal halide, a metal nitride halide, or a metal oxohalide. In embodiments, the metal halide compound is a metal halide. Metal halides consist of the metal atom bonded to one or more halogen atoms.

In embodiments, the metal may be selected from a list consisting of: a transition metal, a metal from the lanthanide series, and combinations thereof. In some embodiments, the metal may be selected from a list consisting of: cobalt, ruthenium, manganese, nickel, a group 3 metal, a metal from the lanthanide series, and combinations thereof. The group 3 metals include scandium, yttrium, lutetium, and lawrencium. In some embodiments, the group 3 metal is scandium and/or yttrium. The lanthanides include lanthanum, cerium, praseodymium, neodymium, promethium, samarium, europium, gadolinium, terbium, dysprosium, holmium, erbium, thulium, ytterbium, and lutetium. These metals are considered to be important for semiconductor applications, but halide compounds of these metals typically have very high volatilization temperatures.

In some embodiments, the metal halide compound is selected from a group consisting of: LaCl₃, YCl₃, ScCl₃, or combinations thereof. In these embodiments, the carrier agent preferably comprises, or consists of, AlCl₃. In these embodiments, the multinuclear complex comprising the group 13 halide coordinated with the metal halide compound may have the following formula: M″Cl₃(AlCl₃), with metal M″ selected from La, Y and Sc. In some of these embodiments, the deposition method may be atomic layer deposition, wherein the composition is alternatingly introduced into the reaction chamber, alternating with a co-reactant for providing a thin film of an oxide, a nitride, a carbide, a boride, or a (pure, i.e., metallic) metal, of said metal M″.

In embodiments, the one or more halogen atoms of the metal halide compound may be selected from a list consisting of: fluorine, chlorine, bromine, iodine, and combinations thereof. In some embodiments, each of the one or more halogen atoms of the metal halide compound is bromine or chlorine, preferably chlorine.

In embodiments, the group 13 halide is a group 13 element bonded to one or more halogen atoms. In some embodiments, the carrier agent, in particular, the group 13 halide, may have a volatilization temperature of at most 400° C., preferably at most 300° C., more preferably at most 250° C., even more preferably at most 200° C., under said pressure within the precursor vessel.

In embodiments, the group 13 element may be selected from a list consisting of: boron, aluminum, gallium, and combinations thereof. In some embodiments, the group 13 element is aluminum.

In embodiments, the one or more halogen atoms of the group 13 halide may be selected from a list consisting of: fluorine, chlorine, bromine, iodine, and combinations thereof. In some embodiments, each of the one or more halogen atoms of the group 13 halide is bromine or chlorine, preferably chlorine. In some embodiments, the group 13 halide is selected from a list consisting of: aluminum trichloride, aluminum tribromide, aluminum triiodide, gallium trichloride, gallium tribromide, boron trichloride, boron tribromide, boron trifluoride, indium trichloride, and combinations thereof. In some embodiments, the group 13 halide is aluminum trichloride. It is an advantage of these embodiments that these carrier agents may be effective carrier agents having a volatilization temperature that is well within the typical temperature range under normal chemical vapor phase deposition processing conditions.

In some embodiments, the halogen atoms of the group 13 halide are of the same type (that is, same type of element) as the halogen atoms of the metal halide compound. For example, both the metal halide compound and the group 13 halide may be chlorides. This may—as a result of spatial similarity between the metal halide compound and the group 13 halide resulting in good interactions—result in good transportation of the metal halide compound by the group 13 halide.

In some embodiments, the precursor vessel comprises the metal halide compound in a condensed phase. The metal halide compound may also be at least partially in the condensed phase while performing a chemical vapor phase deposition technique. In some embodiments, the precursor vessel may comprise the metal halide compound in a polymeric, non-crystalline (e.g., amorphous), crystalline or liquid state. In some embodiments, the precursor vessel may comprise the metal halide compound in a polymeric or crystalline state. Most metal halide compounds form, in the condensed phase, polymeric or crystalline phases.

In some embodiments, the precursor vessel may comprise the metal halide compound dispersed in a liquid matrix, preferably in an ionic liquid. Ionic liquids are salts having a melting point that is typically below 100° C. under standard pressure (i.e., 1 atm., equivalent to 101325 Pa). For example, the precursor vessel may comprise polymeric, non-crystalline (e.g., amorphous), or crystalline metal halide compound particles dispersed in the liquid matrix. During a chemical vapor deposition process, the carrier agent comprising the group 13 halide, when in the vapor phase, may be bubbled through the liquid matrix, thereby transferring at least part of the metal halide compound into the vapor phase.

The group 13 halide may be present in the precursor vessel during storage. Alternatively, during storage, the precursor vessel comprises only the metal halide compound, in which case the group 13 halide may be introduced into the precursor vessel when the precursor vessel is used in a method of chemical vapor deposition. The group 13 halide may be present in the precursor vessel in a condensed state or in a vapor phase. During a chemical vapor deposition process, the group 13 halide is typically present in the precursor vessel in the vapor phase.

The precursor vessel may be fabricated of a suitable vessel material, such as stainless steel, aluminum, copper, nickel, silver, their alloys, graphite, boron nitride, ceramic material or a combination or a mixture of said materials. The vessel material may be a heat-conducting material. The vessel material may be a coated or clad material.

The precursor vessel comprises a housing defining an interior volume of the precursor vessel. The interior volume is adapted for holding the precursor and the carrier agent according to embodiments of the present invention. In some embodiments, the interior volume has a substantially circular cylindrical shape, so that the interior volume has a substantially circular floor. However, the interior volume of the precursor vessel may have any shape that facilitates an even flow of carrier gas and carrier agent through the interior volume. In some embodiments, the precursor vessel may have a height to width aspect ratio in the range of about 0.5 to 4, for example, 1 to 2 or 1 to 3. The height of the precursor vessel is a dimension at an exterior of the precursor vessel from a lid to a portion of the housing farthest away from the lid. The width of the precursor vessel is a largest dimension across the precursor vessel perpendicular to the height.

In some embodiments, the internal volume comprises a single chamber for storing the metal halide compound and optionally the group 13 halide. In some embodiments, the interior volume may be divided into a plurality of chambers. In some embodiments, the precursor vessel comprises at least one first chamber comprising the chemical precursor comprising the metal halide compound, and at least one second chamber comprising the carrier agent comprising the group 13 halide. The chambers may be coupled to each other via valves. The valves may be closed, e.g., during storage and transportation of the precursor vessel, to prevent the materials in the different chambers to mix with, or contact, each other. The valves may be opened, e.g., when the precursor vessel is used in a chemical vapor deposition method, so that the carrier agent comprising the group 13 halide may flow, in the vapor phase, from the at least one second chamber into the at least one first chamber, for transporting the metal halide compound into the vapor phase. Each first chamber may be coupled, via a valve, to one of the one or more second chambers, so that the group 13 halide passes, from the second chamber, through the first chamber before leaving the precursor vessel via an outlet of the precursor vessel. The one or more first chambers and the one or more second chambers may be coupled, via the valves, in series, or pairs of a first chamber and a second chamber may be coupled, within each pair, in series, whereas the pairs may be coupled in parallel with each other.

In some embodiments, said pressure within the precursor vessel (on which the volatilization temperature of the metal halide compound and of the group 13 halide depends) may refer to a pressure within the interior volume of the precursor vessel, such as within a first chamber in which the metal halide compound is present.

In some embodiments, the precursor vessel comprises a lid for isolating the interior volume from the surrounding atmosphere. In some embodiments, the lid may comprise an inlet for feeding a carrier gas (e.g., N₂, He or Ar) into the interior volume of the precursor vessel. In some embodiments, the precursor vessel may comprise an inlet for feeding the group 13 halide into the interior volume of the precursor vessel. In some embodiments, the inlet for feeding the group 13 halide may also provide the carrier gas. The inlet for feeding the carrier gas and/or carrier agent may comprise an inlet valve for introducing said carrier gas and/or carrier agent when the inlet valve is open, and for blocking said carrier gas and/or carrier agent from being fed into the precursor vessel when the inlet valve is closed. The lid may comprise an outlet for feeding the carrier agent together with the chemical precursor, and optionally the carrier gas, to the reaction chamber. The outlet may comprise an outlet valve for providing said carrier agent together with the chemical precursor, and optionally the carrier gas, to the reaction chamber when the outlet valve is open, and for blocking said carrier agent together with the chemical precursor, and optionally the carrier gas, from being fed to the reaction chamber when the outlet valve is closed.

The precursor vessel may be provided with gas lines extending from the inlet and outlet, isolation valves on the lines, and fittings on the valves, the fittings being configured to connect to gas flow lines of other components of a chemical vapor deposition system. Isolation valves may fluidically isolate the contents of the precursor vessel from the vessel exterior. One isolation valve may be provided upstream of the precursor vessel inlet, and another isolation valve may be provided downstream of the precursor vessel outlet.

The precursor vessel, or a deposition system of which the precursor vessel may be part, may comprise a heater, such as a radiant heat lamp or resistive heaters. In some embodiments, the heater may be adapted to heat the precursor vessel to a temperature of from 40° C. to 200° C., for example, to 70° C., 85° C., 90° C., 110° C. or 120° C. In particular, during use of the precursor vessel in a chemical vapor deposition method, the heater may be configured to heat the precursor vessel to a temperature above a volatilization temperature, under a pressure within the precursor vessel, of the group 13 halide. More particularly, the heater may be configured to heat the precursor vessel to a temperature wherein a vapor phase may contain, under a pressure within the precursor vessel, the multinuclear complex comprising the group 13 halide coordinated with the metal halide compound. That is, the temperature is preferably sufficiently high so that the multinuclear complex may be in the vapor phase, and preferably sufficiently low to prevent decomposition of the multinuclear complex, e.g., into the metal halide compound dissociated from the group 13 halide.

In embodiments, the pressure within the precursor vessel may be from 10 to 1000 Pa, although the invention is not limited thereto. In particular, during use in a chemical vapor deposition method, precursor vessels are typically at such a low pressure. The precursor vessel may comprise, or may be coupled to, a pressure control system, for monitoring a pressure in the precursor vessel. The precursor vessel may comprise a valve for coupling the precursor vessel to a vacuum pump.

In some embodiments, the precursor vessel may comprise precursor distribution means for enabling efficient precursor vaporization, e.g., precursor holding structures or carrier gas guiding arrangements in the interior volume of the precursor vessel. The precursor vessel may comprise features for filtering solid particles, to prevent such particles from being present in the vapor phase flow, such as filters or other entrapment structures. Additionally, the inlet and the outlet of the precursor vessel, as well as gas lines extending therefrom, may comprise heaters for heating the valves and gas lines between the precursor vessel and the reaction chamber to prevent the reactant vapor from condensing and depositing on any components.

Any features of any embodiment of the first aspect may be independently as correspondingly described for any embodiment of any of the other aspects of the present invention.

In a second aspect, the present invention relates to a method for chemical vapor depositing a material comprising a metal on a substrate, the method comprising:
a. providing the substrate in a reaction chamber, and then
b. providing, from a first source, into the reaction chamber, a vapor-phase composition comprising a multinuclear complex comprising:
   (i). a chemical precursor comprising a halide compound of the metal, the metal halide compound having a volatilization temperature, under a pressure at a location along a flow path of the composition from the first source to the reaction chamber, above a temperature at said location, coordinated with
   (ii). a carrier agent for transporting said metal halide compound in the vapor phase, the carrier agent comprising a group 13 halide having a volatilization temperature, under said pressure, below said temperature, thereby forming a thin film comprising the metal on a portion of a surface of the substrate.

The composition and the multinuclear complex are described in the first aspect of the present disclosure.

The flow path of the composition from the first source to the reaction chamber is understood to include a flow path of the composition within the first source, a flow path of the composition within the reaction chamber, and - if the first source and the reaction chamber are not directly connected with each other - a flow path of the composition between the first source and the reaction chamber. In some embodiments, the location may comprise the first source, such as an interior volume or chamber of the precursor vessel in accordance with embodiments of the first aspect of the present invention in which the metal halide compound may be present or stored. In some embodiments, the location may comprise the reaction chamber, in particular, an environment within the reaction chamber. In some embodiments, the location may comprise a flow path, e.g., through gas lines and/or valves, between the first source and the reaction chamber. In some embodiments, the location comprises substantially said complete flow path of the composition from the first source to the reaction chamber. In some embodiments, the location comprises substantially the complete first source, substantially the complete reaction chamber, and substantially the complete flow path of the composition between the first source and the reaction chamber. As such, although the metal halide compound would normally be in a condensed phase throughout at least part of the flow path from the first source in which it is stored, to the substrate, it may be transported along said flow path by the group 13 halide.

Said temperature at the location, or along substantially said complete flow path, is adapted so that said multinuclear complex, comprising the metal halide compound coordinated to the group 13 halide, is in the vapor phase. Typically, the multinuclear complex may be formed when it encounters or contacts the group 13 halide in the vapor phase. That is, the group 13 halide being in the vapor phase typically suffices for the multinuclear complex to be in the vapor phase as well. Said temperature at the location is typically higher than a volatilization temperature, under a pressure at said location, of said multinuclear complex. Said temperature along substantially said complete flow path may be higher than the volatilization temperature, dependent on pressure, of said multinuclear complex.

In embodiments, the first source comprises the precursor vessel, in accordance with embodiments of the first aspect of the present invention, comprising both the metal halide compound and the group 13 halide (separate or contained in said multinuclear complex). In some embodiments, the first source comprises a carrier agent vessel comprising the group 13 halide, and the precursor vessel for storing the metal halide compound. In these embodiments, providing the vapor-phase composition may comprise providing the group 13 halide into the vapor phase in the carrier agent vessel (e.g., by heating using a heater), and inducing a flow of the vapor-phase group 13 halide from the carrier agent vessel into the precursor vessel. The vapor-phase group 13 halide may coordinate to the metal halide compound and transport the metal halide compound into the vapor phase, thereby forming said vapor-phase composition. The vapor-phase composition may, subsequently, be transferred from the precursor vessel into the reaction chamber.

The substrate being provided in the reaction chamber typically means that the substrate is in a space where deposition conditions can be controlled. The reaction chamber may be a single wafer reactor. Alternatively, the reaction chamber may be a batch reactor. The reaction chamber can form part of a vapor processing assembly for manufacturing semiconductor devices. The processing assembly may comprise one or more multi-station processing chambers. In some embodiments, the substrate is moved between processing stations of a multi-station processing chamber. The reaction chamber may be part of a cluster tool in which different processes are performed to form an integrated circuit. Various phases of the chemical vapor deposition method can be performed within a single reaction chamber, or they can be performed in multiple reaction chambers, such as reaction chambers of a cluster tool, or deposition stations of a multi-station processing chamber.

In embodiments, the reaction chamber is a reaction chamber of a semiconductor processing apparatus. In some embodiments, the reaction chamber may be a flow-type reactor, such as a cross-flow reactor. In some embodiments, the reaction chamber may be a showerhead reactor. In some embodiments, the reaction chamber may be a space-divided reactor. In some embodiments, the reaction chamber may be a single wafer atomic layer deposition reactor. In some embodiments, the reaction chamber may be a high-volume manufacturing single wafer atomic layer deposition reactor. In some embodiments, the reaction chamber may be a batch reactor for manufacturing multiple substrates simultaneously.

The reaction chamber may form part of a chemical vapor deposition system. In some embodiments, said chemical vapor deposition is atomic layer deposition. The reaction chamber can form part of an atomic layer deposition system. In some embodiments, the system or the reaction chamber may be provided with a heater to activate reactions by elevating the temperature of one or more of the substrate and/or precursors and/or co-reactants.

The substrate may be a semiconductor wafer, such as a silicon wafer, a gallium arsenide wafer, a silicon carbide wafer, a germanium wafer, or an indium phosphide wafer, although the invention is not limited thereto. In embodiments, the portion of the surface of the substrate is reactive towards the metal halide compound, or towards the multinuclear complex comprising the metal halide compound and the group 13 halide. In some embodiments, the portion of the surface of the substrate may be functionalized for facilitating chemical adsorption of the metal halide compound, or of said multinuclear complex, on said portion of the surface. In some embodiments, the portion of the surface may be functionalized with a functional group selected from a group consisting of: hydroxyl groups, amino groups, carboxyl groups, thiols, silane groups, or combinations thereof.

In what follows, different types of chemical vapor deposition are described in detail, which may be performed in accordance with embodiments of the present invention, but the invention is not limited thereto.

In some embodiments, a substrate temperature of the portion of the surface may be adapted so that chemical adsorption of the metal halide compound is induced on the substrate. Said chemical adsorption reaction is typically of the metal halide compound with the surface, e.g., with a functional group of the surface. Said chemical adsorption reaction may occur directly, with the composition being in the vapor-phase. In some embodiments, said substrate temperature may be adapted so that said adsorption occurs selectively for the metal halide compound, with respect to adsorption of the group 13 halide. In these embodiments, the substrate temperature may be adapted so that the group 13 halide dissociates from the metal halide compound when the multinuclear complex touches the portion of the surface, so that the thin film contains only chemically adsorbed metal halide compound. In different embodiments, said substrate temperature is adapted so that chemical adsorption of the multinuclear complex occurs on the portion of the surface of the substrate, so that the thin film may comprise the chemically adsorbed multinuclear complex.

The chemically adsorbed metal halide compound may comprise the metal of the metal halide compound bonded to the portion of the surface of the substrate, wherein one or more halogen atoms of the metal halide compound may remain bonded to the metal atom. If the metal halide compound is the metal oxo-halide, the chemically adsorbed metal halide compound may further comprise an oxygen atom bonded to said metal. If the metal halide compound is the metal nitride halide, the chemically adsorbed metal halide compound may further comprise a nitrogen atom bonded to said metal. The chemically adsorbed multinuclear complex, bonded to the surface, may comprise the metal of the metal halide compound and the group 13 element, and optionally one or more halogen atoms and/or oxygen atoms and/or nitrogen atoms of the metal halide compound and/or the group 13 halide.

If the thin film contains the chemically adsorbed multinuclear complex, but if it is unwanted that the group 13 element remains present to be incorporated in the material to be deposited, the method may comprise a further step of inducing selective release of the group 13 halide from the thin film. The portion of the surface may be heated, and/or the pressure of the environment within the reaction chamber may be adapted, so as to selectively release the group 13 halide from the chemically adsorbed multinuclear complex, with chemically adsorbed metal halide compound remaining on the surface. Before and/or during said heating, the reaction chamber may be purged of the group 13 halide, which may facilitate said release.

In some embodiments, said chemical adsorption process may be self-limiting, for example, if the chemically adsorbed metal halide compound does not readily react with the vapor-phase multinuclear complex. In these embodiments, the chemical adsorption process may, for example, be limited by a size of a reactive area on the surface, or by the number of functional groups present on the portion of the surface of the substrate. These embodiments may relate to atomic layer deposition. The thin film may, in these embodiments, contain a single layer of the chemically adsorbed metal halide compound, or of the chemically adsorbed multinuclear complex, the single layer having a thickness that is substantially equal to the size of a single chemically adsorbed metal halide compound or of a single chemically adsorbed multinuclear complex.

In some embodiments, however, this chemical adsorption process is not self-limiting. For example, the vapor-phase multinuclear complex may be adapted to react with the metal halide compound or the multinuclear complex chemically adsorbed on the surface, in which case the chemical vapor deposition may proceed to form a plurality of atomic layers on the portion of the surface. In these embodiments, a time during which the portion of the surface is exposed to the composition may be adapted so as to form a thin layer having a particular preferred thickness.

In some embodiments, the substrate temperature may be adapted so as to induce non-reactive deposition of the vapor, without, initially undergoing a reaction, such as physical adsorption or condensation (that is, a transition from the vapor phase to a condensed phase, without, initially, a reaction), followed by a chemical reaction of the deposited material with the surface. In these embodiments, the formed thin film, formed after said deposition but before said reaction, may comprise the metal halide compound or the multinuclear complex. In some embodiments, the substrate temperature of the portion of the surface of the substrate may be lower than the volatilization temperature of the group 13 halide, under the pressure in the reaction chamber. In some of these embodiments, the substrate temperature of the portion of the surface of the substrate may be low enough so that, initially, non-reactive deposition of the multinuclear complex may be induced. In some embodiments, the substrate temperature of the portion of the surface of the substrate may, however, be adapted so that selective non-reactive deposition of the group 13 halide (but not the multinuclear complex) is induced. In these embodiments, the multinuclear complex may contact the portion of the substrate, on which dissociation of the metal halide compound from the group 13 halide occurs, wherein the metal halide compound is deposited while the group 13 halide may remain in the vapor-phase.

Said non-reactive deposition itself may or may not be self-limiting. The substrate temperature, the temperature of the environment within the reaction chamber, a concentration of the precursor and the carrier agent within the reaction chamber, and a time between providing the composition into the reaction chamber and purging of the composition from the reaction chamber, may be adapted so as to achieve a particular amount, e.g., a single molecule thick layer, of the metal halide compound or the multinuclear complex on the portion of the surface.

In embodiments wherein the formed thin film comprises the multinuclear complex, the method may comprise a further step of inducing selective release of the group 13 halide from the thin film. In some embodiments, inducing said selective release may comprise adapting (e.g., increasing) the temperature of the portion of the surface of the substrate, so that the group 13 halide is released from the surface, while the metal halide compound remains on the surface. In particular, the temperature of the portion of the surface of the substrate may—during said selective release—be above the volatilization temperature, under the pressure of said environment within the reaction chamber, of the group 13 halide, and below the volatilization temperature, under the pressure of said environment within the reaction chamber, of the metal halide compound. The temperature may be adapted so that decomposition of the multinuclear complex occurs, e.g., breaking of bonds between the metal halide compound and the halide of a group 13 compound, resulting in said release. In order to facilitate said release, the reaction chamber may be purged of the group 13 halide. It is an advantage of these embodiments that a thin film may be formed comprising the metal halide compound but substantially not comprising the group 13 halide.

The formed thin film comprising the metal halide compound or the multinuclear complex may subsequently be induced to react with the surface. In particular, the temperature of the portion of the surface of the substrate may be adapted so as to induce a reaction of the metal halide compound or the multinuclear complex on the portion of the surface, with said portion of the surface, e.g., with functional groups on said portion of the surface. Said reaction may be self-limiting, although this is not essential, similarly as described above for the chemical adsorption process. Said reaction may result in chemically adsorbed metal halide compound or chemically adsorbed multinuclear complex on the portion of the surface.

In some embodiments, the present invention relates to cyclical chemical vapor deposition processes, such as atomic layer deposition. In cyclic chemical vapor deposition processes, during each cycle, the composition is introduced into the reaction chamber, and the metal halide compound or the multinuclear complex may be chemically adsorbed (or chemisorbed) onto the substrate surface, in a self-limiting way, as described above. Thereafter, a co-reactant may be introduced into the reaction chamber for converting the chemisorbed metal halide compound or multinuclear complex to a desired material. The co-reactant may be capable of further reaction with the chemically adsorbed metal halide compound or multinuclear complex. Also, the deposition of the co-reactant may be self-limiting, in that the co-reactant may not readily react with the co-reactant. Purging steps may be utilized to remove any excess precursor and carrier agent from the process chamber and/or remove any excess co-reactant and/or reaction byproducts from the reaction chamber.

When the vapor-phase composition is introduced after deposition of the co-reactant into the reaction chamber again, the metal halide compound or the multinuclear complex reacts with the deposited co-reactant, or with the chemically adsorbed metal halide compound or multinuclear complex after reaction with the co-reactant, to become chemically adsorbed thereon, open again for reaction with the co-reactant. This cycle of providing the vapor-phase deposition and the co-reactant may be repeated a plurality of times.

In some embodiments, the cyclic chemical vapor deposition process comprises, after providing the vapor-phase composition into the reaction chamber, cyclically:
optionally purging the reaction chamber of said vapor-phase composition, then
introducing, from a second source, such as from a co-reactant vessel, into the reaction chamber, a vapor-phase co-reactant, then
optionally purging the reaction chamber of said co-reactant, then providing, from the first source, into the reaction chamber, the vapor-phase composition, and then
optionally inducing said selective release of the group 13 halide, if present on the surface.

In some embodiments, at least one cycle of a cyclic chemical vapor deposition process comprises:
from the first source, into the reaction chamber, the vapor-phase composition;
optionally purging the reaction chamber of said vapor-phase composition;
introducing, from a second source, such as from a co-reactant vessel, into the reaction chamber, a vapor-phase co-reactant;
optionally purging the reaction chamber of said co-reactant; and
optionally inducing said selective release of the group 13 halide, if present on the surface.

In some embodiments, the co-reactant may be an oxygen precursor, and the material formed by the cyclic chemical vapor deposition process is an oxide of the metal, from the metal halide compound, and optionally of the group 13 element. The oxygen precursor may provide oxygen for forming said oxide. The oxygen precursor may be a gas or a material that can become gaseous and that can be represented by a chemical formula that includes oxygen. In some embodiments, the oxygen precursor is selected from a group that consists of water, molecular oxygen, hydrogen peroxide, ozone and reactive oxygen species. In some embodiments, the oxygen precursor comprises hydrogen and oxygen. In some embodiments, the oxygen precursor does not contain carbon, i.e., is carbon-free. In some embodiments, the oxygen precursor does not contain silicon, i.e., is silicon-free. In some embodiments, the oxygen precursor comprises water. In some embodiments, the oxygen precursor is water. In some embodiments, the oxygen precursor is molecular oxygen. In some embodiments, the oxygen precursor comprises hydrogen peroxide. In some embodiments, the oxygen precursor is hydrogen peroxide. In some embodiments, the oxygen precursor is ozone. Depending on the selected oxygen precursor, the oxygen precursor may be liquid or gaseous in a co-reactant vessel. However, the invention is not limited thereto, and instead, solid precursors may be used.

In some embodiments, the co-reactant may be a nitrogen precursor, and the material formed by the cyclic chemical vapor deposition process is a nitride of the metal, from the metal halide compound, and optionally of the group 13 element. The nitrogen precursor may provide nitrogen for forming said nitride. The term nitrogen precursor may refer to a gas or a material that can become gaseous and that can be represented by a chemical formula that includes nitrogen. In some embodiments, the chemical formula includes nitrogen and hydrogen. In some embodiments, the nitrogen precursor comprises activated nitrogen species that may be generated in a plasma, such as an N₂ plasma or an N₂+H₂ plasma. In these embodiments, a gas, comprising nitrogen gas, optionally further comprising hydrogen gas, may be introduced into the reaction chamber and may be transformed into the plasma, for example by heating, electrical discharge, or laser ionization. In some embodiments, the nitrogen precursor does not include diatomic nitrogen. In some embodiments, the nitrogen precursor may be selected from one or more of ammonia (NH₃), hydrazine (N₂H4), and other compounds comprising or consisting of nitrogen and hydrogen. For example, a mixture of nitrogen gas and hydrogen gas may be used. In some embodiments, the nitrogen precursor does not include diatomic nitrogen, i.e., the nitrogen precursor is a non-diatomic precursor. In some embodiments, the nitrogen precursor is selected from a list consisting of molecular nitrogen (N₂), ammonia (NH₃), hydrazine (NH2NH2) and a hydrazine derivative, such as tert-butylhydrazine. In some embodiments, the nitrogen precursor does not contain carbon, i.e., the nitrogen precursor may be carbon-free. In some embodiments, the nitrogen precursor does not contain silicon, i.e., the nitrogen precursor may be silicon-free. Depending on the selected nitrogen precursor, the nitrogen precursor may be liquid or gaseous in the co-reactant vessel upon vaporization. However, the invention is not limited thereto, and the nitrogen precursor may be solid. In some embodiments, the nitrogen precursor comprises ammonia. In some embodiments, the nitrogen precursor consists essentially of, or consists of, ammonia. In some embodiments, the nitrogen precursor comprises an alkylamine. In some embodiments, the nitrogen precursor consists essentially of, or consists of, an alkylamine. Examples of alkylamines include dimethylamine, n-butylamine and tert-butylamine. In some embodiments, the nitrogen precursor comprises hydrazine. In some embodiments, the nitrogen precursor consists essentially of, or consists of, hydrazine. In some embodiments, the nitrogen precursor comprises hydrazine substituted by one or more alkyl or aryl substituents. In some embodiments, the nitrogen precursor consists essentially of, or consists of, hydrazine substituted by one or more alkyl or aryl substituents. In some embodiments, the hydrazine derivative comprises an alkyl-hydrazine including at least one of: tert-butylhydrazine (C₄H₉N₂H₃), methylhydrazine (CH₃NHNH₂), 1,1-dimethylhydrazine ((CH₃)₂NNH₂), 1,2-dimethylhydrazine (CH₃NHNHCH₃), ethylhydrazine, 1,1-diethylhydrazine, 1-ethyl-1-methylhydrazine, isopropylhydrazine, phenylhydrazine, 1,1-diphenylhydrazine, 1,2-diphenylhydrazine, N-aminopiperidine, N-aminopyrrole, N-aminopyrrolidine, N-methyl-N-phenylhydrazine, 1-amino-1,2,3,4-tetrahydroquinoline, N-aminopiperazine, 1,1-dibenzylhydrazine, 1,2-dibenzylhydrazine, 1-ethyl-1-phenylhydrazine, 1-aminoazepane, 1-methyl-1-(m-tolyl)hydrazine, 1-ethyl-1-(p-tolyl)hydrazine, 1-aminoimidazole, 1-amino-2,6-dimethylpiperidine, N-aminoaziridine, and azo-tert-butane.

In some embodiments, the co-reactant may be a hydrocarbon. In these embodiments, the material that is formed on the portion of the surface may be a carbide. The hydrocarbon may be aliphatic or aromatic. The hydrocarbon may be saturated or unsaturated, linear or branched, cyclic or acyclic. The hydrocarbon may comprise, for example, an alkyl halide, an alkene, an alkyne, or metal alkyl. In some embodiments, the hydrocarbon is an unsubstituted hydrocarbon, i.e. it comprises only carbon and hydrogen. In some embodiments, the hydrocarbon is a substituted or a functionalized hydrocarbon. For example, the hydrocarbon may be a halogenated hydrocarbon, such as a chlorinated hydrocarbon, a fluorinated hydrocarbon, a brominated hydrocarbon, or an iodinated hydrocarbon. The hydrocarbon may be a hydroxylated hydrocarbon, an alcohol, or a carboxylic acid. The hydrocarbon may be an ester, a ketone or an aldehyde. The hydrocarbon may comprise an amine or an imine.

In some embodiments, the co-reactant may comprise boron. In these embodiments, the material that is formed on the portion of the surface may be a metal boride. In these embodiments, the co-reactant may comprise B₂H₆, adducts of BH₃, or higher order boranes of the formula BxHy.

In some embodiments, the co-reactant may be a reducing agent. In these embodiments, the material formed by the cyclic chemical vapor deposition method on the portion of the surface is a metallic material that may substantially consist of the metal of the metal halide compound and optionally of the group 13 element (if it is metallic, e.g., Al, Ga or In), may be formed. The reducing agent may be a gas or a material that can become gaseous and that can reduce the deposited or chemically adsorbed metal halide compound or multinuclear complex into metal. The reducing agent may be provided to the reaction chamber in a gas or vapor phase. The reducing agent may be contacted with the substrate comprising the metal halide compound or multinuclear complex chemisorbed to the substrate. The introduction of the vapor-phase composition and the reducing agent into the reaction chamber may at least partially overlap. In some embodiments, the introduction of the vapor-phase composition and the reducing agent into the reaction chamber may be simultaneous. However, in some embodiments, introduction of the vapor-phase composition and the reducing agent into the reaction chamber may be at least partially separate. In some embodiments, the reducing agent may comprise hydrogen. In some embodiments, the reducing agent may comprise molecular hydrogen (H₂) or plasma derived from H₂. In some embodiments, the reducing agent may comprise boron. In some embodiments, the reducing agent comprises, consists essentially of, or consists of, diborane (B₂H₆) or neutral ligand adducts of borane (BH₃). In some embodiments, the reducing agent comprises nitrogen. In some embodiments, the reducing agent may comprise, consist essentially of, or consist of, hydrazine, or a derivative thereof. In some embodiments, the reducing agent may comprise an alkylhydrazine or a dialkylhydrazine. In some embodiments, the reducing agent may comprise a diazenyl compound. The diazenyl compound may be azo-tert-butane. In some embodiments, the reducing agent may comprise, consist essentially of, or consist of 1,1-diethylhydrazine, 1-ethyl-1-methylhydrazine, isopropylhydrazine, phenylhydrazine, 1,1-diphenylhydrazine, 1,2-diphenylhydrazine, N-aminopiperidine, N-aminopyrrole, N-aminopyrrolidine, N-methyl-N-phenylhydrazine, 1-amino-1,2,3,4-tetrahydroquinoline, N-aminopiperazine, 1,1-dibenzylhydrazine, 1,2-dibenzylhydrazine, 1-ethyl-1-phenylhydrazine, 1-aminoazepane, 1-methyl-1-(m-tolyl)hydrazine, 1-ethyl-1-(p-tolyl)hydrazine, 1-aminoimidazole, 1-amino-2,6-dimethylpiperidine, N-aminoaziridine, or azo-tert-butane. In some embodiments, the reducing agent may comprise, consist essentially of, or consist of one or more hydrocarbon-substituted hydrazine reducing agents. In some embodiments, the substituted hydrazine may comprise one or more alkyl groups. Each alkyl group may comprise one or more, such as two, three, four, five, six, seven or eight carbon atoms. The number of alkyl groups in a substituted hydrazine reducing agent may be one, two, three or four. For the purposes of the current disclosure, an alkyl group may be an aryl group. Thus, the reducing agent according to the current disclosure may comprise phenyl hydrazine, or diphenyl hydrazine, for example.

In some embodiments, the vapor-phase composition and the co-reactant are provided into the reaction chamber in pulses. In some embodiments, the vapor-phase composition is supplied in pulses and the co-reactant is supplied in pulses, and the reaction chamber is purged between consecutive pulses of the precursor comprising the multinuclear complex and the co-reactant. A duration of providing the vapor-phase composition and the co-reactant into the reaction chamber (i.e., a pulse time for the vapor-phase composition, and a pulse time for the co-reactant, respectively) may each independently be, for example, at least 0.01 s, e.g., from about 0.01 s to about 60 s, for example from about 0.01 s to about 5 s, or from about 1 s to about 20 s, or from about 0.5 s to about 10 s, or from about 5 s to about 15 s, or from about 10 s to about 30 s, or from about 10 s to about 60 s, or from about 20 s to about 60 s, for example, 0.03 s, 0.1 s, 0.5 s, 1 s, 1.5 s, 2 s, 2.5 s, 3 s, 4 s, 5 s, 8 s, 10 s, 12 s, 15 s, 25 s, 30 s, 40 s, 50 s or 60 s. In some embodiments, vapor-phase composition pulse time may be at least 5 seconds, or at least 10 seconds. In some embodiments, vapor-phase composition pulse time may be at most 5 seconds, or at most 10 seconds or at most 20 seconds, or at most 30 seconds. In some embodiments, co-reactant pulse time may be at least 5 seconds, or at least 10 seconds, or at least 20 seconds. In some embodiments, co-reactant pulse time may be at most 5 seconds, or at most 10 seconds or at most 20 seconds, or at most 30 seconds. The pulse times may vary independently from each other, and may be dependent on the process in question. The selection of an appropriate pulse time may depend on the substrate topology. For higher aspect ratio structures, longer pulse times may be needed to obtain sufficient surface saturation in different areas of a high aspect ratio structure. Also, the selected precursor and co-reactant chemistries may influence suitable pulsing times. For process optimization purposes, shorter pulse times might be preferred as long as appropriate layer properties can be achieved. In some embodiments, vapor-phase composition pulse time is longer than co-reactant pulse time. In some embodiments, co-reactant pulse time is longer than vapor-phase composition pulse time. In some embodiments, vapor-phase composition pulse time is the same as co-reactant pulse time. In some embodiments, the vapor-phase composition may be pulsed more than one time, for example two, three or four times, before the co-reactant is pulsed to the reaction chamber. Similarly, there may be more than one pulse, such as two, three or four pulses, of the co-reactant before the vapor-phase composition is pulsed (i.e., provided) into the reaction chamber.

In some embodiments, one of more purging steps are performed to remove any precursor, carrier agent, co-reactants, and/or vapor phase byproducts from the reaction chamber. Purging may comprise evacuating the reaction chamber with a vacuum pump and/or by replacing the gas inside a reaction chamber with an inert or substantially inert gas such as argon or nitrogen. Purging may limit or prevent interactions between, for example, the precursor and the co-reactant in the vapor phase. Purging may be effected either in time or in space, or both. In some embodiments, a purge step may comprise providing a purge gas to the reaction chamber while simultaneously pumping gas from the reaction chamber, wherein the substrate on which the layer is deposited does not move. Said purging step may be performed for from about 0.01 seconds to about 20 seconds, from about 0.05 s to about 20 s, or from about 1 s to about 20 s, or from about 0.5 s to about 10 s, or between about 1 s and about 7 seconds, such as 5 s, 6 s or 8 s, but other purge times can be utilized if necessary. In some embodiments, a purge step may comprise:
moving the substrate from a first location to which the vapor-phase composition is continuously supplied, to a second location to which the co-reactant is continuously supplied, through a purge gas curtain or another means of separating the first location from the second location.

Any features of any embodiment of the second aspect may be independently as correspondingly described for any embodiment of any of the other aspects of the present invention.

In a third aspect, the present invention relates to a system for chemical vapor depositing a material comprising a metal, the system comprising:
a. a reaction chamber for receiving the substrate,
b. a first source, coupled to the reaction chamber via a first valve, for providing a vapor-phase composition comprising a multinuclear complex comprising:
   (i). a chemical precursor comprising a halide compound of the metal, coordinated with
   (ii). a carrier agent for transporting said chemical precursor in the vapor phase, the carrier agent comprising a group 13 halide, and
c. a controller operably connected to the first valve, wherein the controller is configured and programmed to open the first valve to provide a flow of the composition into the reaction chamber and to close the first valve to cease the flow of the composition into the reaction chamber, wherein the system is configured for, when said first valve is open, providing a temperature and a pressure at a location along a flow path of the composition from the first source to the reaction chamber, wherein a volatilization temperature, under said pressure, of the metal halide compound is above said temperature, and a volatilization temperature, under said pressure, of the group 13 halide is below said temperature.

The composition and the multinuclear complex are described in the first aspect of the present disclosure.

In embodiments, the system is a semiconductor processing apparatus. In embodiments, the reaction chamber comprises the substrate. The first source may comprise the precursor vessel in accordance with embodiments of the first aspect of the present invention.

In The precursor vessel may have an inlet fluidically coupled to a source of a carrier gas. The carrier gas may be an inert gas such as N₂, He or Ar. The carrier gas may sweep a vapor of the group 13 halide, together with the metal halide compound, along with it through the precursor vessel outlet, into the reaction chamber.

In The system may comprise heaters that may be operated by a controller, for keeping the vapor-phase composition at or above the volatilization temperature of the group 13 halide, and at a temperature so that the multinuclear complex comprising the group 13 halide coordinated with the metal halide compound is in the vapor phase, throughout the deposition system so as to prevent undesirable condensation in the valves, filters, conduits, and other components associated with delivering the vapor-phase composition into the reaction chamber. In addition to a heater for heating the precursor vessel, as described elsewhere in the present description, additional heaters may be provided for heating the various valves and gas flow lines between the precursor vessel and the reaction chamber, to prevent the vapor-phase composition from condensing and depositing on such components. Gas-conveying components between the precursor vessel and the reaction chamber may be provided in which the temperature is maintained above the volatilization temperature of the halide of a group 13 compound (i.e., “hot zone”).

In In some embodiments, the system further comprises a second source, e.g., a co-reactant vessel, coupled to the reaction chamber via a second valve. The second source may be for providing a vapor-phase co-reactant. The second source may comprise any source suitable for providing the co-reactant, such as the co-reactant vessel, a compressed gas cylinder, in which the co-reactant may be contained as a pressurized gas, or a co-reactant generator, such as an ozone generator. In these embodiments, the system may further comprise a controller operably connected to the second valve, wherein the controller is configured and programmed to open the second valve to provide a flow of the co-reactant into the reaction chamber and to close the second valve to cease the flow of the co-reactant into the reaction chamber.

In In some embodiments, the system further comprises a device for purging the reaction chamber, such as a device for performing inert gas purging on the reaction chamber or a device for vacuum pumping the reaction chamber. The system may further comprise a controller for activating said purging device to purge the reaction chamber. The controller may be configured and programmed to purge the reaction chamber after closing of the first valve and before opening of the second valve, and/or after closing of the second valve and before opening of the first valve.

In Any features of any embodiment of the third aspect may be independently as correspondingly described for any embodiment of any of the other aspects of the present invention.

In In a fourth aspect, the present invention relates to a composition configured for depositing a thin film by chemical vapor deposition, preferably by atomic layer deposition, the composition comprising:
a. a chemical precursor comprising a metal halide compound, and
b. a carrier agent for transporting said chemical precursor in a vapor phase, the carrier agent comprising a group 13 halide and having, under a pressure within a range of from 10 to 1000 Pa, a volatilization temperature below a volatilization temperature of the metal halide compound.

In The composition is described in the first aspect of the present disclosure. The compositions are typically stable enough for allowing storage and use over an extended period of time, for example, over several months. The composition is typically adapted to withstand the deposition conditions to allow vapor transfer into a reaction chamber. Additionally, the vaporization rate of the composition under predetermined conditions remains preferably constant. Some compositions may suffer from more than one substance being vaporized from the composition (e.g., impurities in the chemical precursor and/or the carrier agent). If the substances differ in volatility, the composition may be enriched in less volatile substances over time. This can lead to a phenomenon called process drift: one or more of the deposition process parameters gradually changes over time as the chemical composition of the composition changes. The consequences of process drift may be detrimental in sensitive applications, and the tuning of the process to compensate for the drift may be expensive, difficult, or even impossible.

In In embodiments, a purity of the composition, e.g., of the metal halide compound and the group 13 halide combined, is at least 95 mol-%, preferably at least 99 mol-%, more preferably at least 99.9 mol-%, even more preferably at least 99.99 mol-%, yet more preferably at least 99.999 mol-%, still more preferably at least 99.9999 mol-%. Such high purities are typically strongly preferred for chemical vapor deposition, in particular, for atomic layer deposition.

In Any features of any embodiment of the fourth aspect may be independently as correspondingly described for any embodiment of any of the other aspects of the present invention.

In in a fifth aspect, the present invention relates to a precursor vessel comprising:
a housing defining an interior volume of the precursor vessel, an inlet conduit, or inlet, seated in the housing and in fluid communication with the interior volume of the precursor vessel, the inlet conduit comprising at least one valve positioned thereon,
an outlet conduit, or outlet, seated in the housing and in fluid communication with the interior volume of the precursor vessel, the outlet conduit comprising at least one valve positioned thereon, and
a metal halide compound impounded within the interior volume of the precursor vessel, wherein the metal halide compound comprises:
   (i) a metal selected from the group consisting of cobalt, ruthenium, manganese, nickel, a group 3 metal, and a metal from the lanthanide series, and
   (ii) one or more halogen atoms.

In embodiments, the precursor vessel is configured to receive a vapor flow of a carrier agent into the interior volume of the precursor vessel and to supply a vapor flow of the metal halide compound and the carrier agent from the interior volume of the precursor vessel.

In embodiments, the metal halide compound is an inorganic compound. In embodiments, the metal halide compound is an inorganic metal halide compound.

In embodiments, the metal halide compound has a vapor pressure of less than about 1 torr, or less than about 0.5 torr, at a temperature ranging from 25° C. to 200° C.

In embodiments, the precursor vessel further comprises the carrier agent comprising a group 13 halide having, under a pressure within the precursor vessel, a volatilization temperature below a volatilization temperature of the metal halide compound.

In embodiments, the precursor vessel further comprises at least one filter coupled to the outlet conduit.

In embodiments, the at least one valve positioned on the outlet conduit and the at least one valve positioned on the inlet conduit are rated for a temperature of at least about 100° C., or at least about 150° C., or at least about 200° C.

In embodiments, the precursor vessel further comprises a precursor distribution means for enabling efficient precursor vaporization, e.g., precursor holding structures or carrier gas guiding arrangements in the interior volume of the precursor vessel. The carrier gas guiding arrangements may be used facilitate flow of the carrier agent into the precursor vessels over the surface or through the metal halide compound.

In embodiments, the metal halide compound has a volatilization temperature of at least about 250° C., at least about 300° C., at least about 400° C., or even at least about 500° C.

In some embodiments, a purity of the metal halide compound is at least 95 mol-%, preferably at least 99 mol-%, more preferably at least 99.9 mol-%, even more preferably at least 99.99 mol-%, yet more preferably at least 99.999 mol-%, still more preferably at least 99.9999 mol-%.

Any features of any embodiments of the precursor vessel of the fifth aspect may be independently as correspondingly described for any embodiments of the precursor vessel of the first aspect of the present invention.

Any features of any embodiment of the fifth aspect may be independently as correspondingly described for any embodiment of any of the other aspects of the present invention.

### Example: Deposition of a Metal Halide Compound

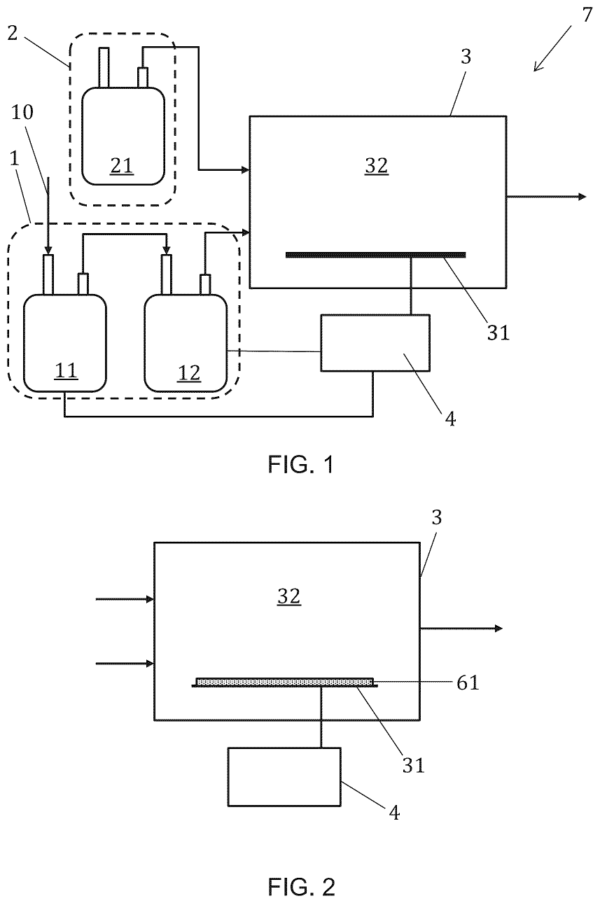

Reference is made to FIG. 1, which is a schematic representation of a system (7) for depositing a material on a substrate (31) in accordance with embodiments of the present invention.

The system (7) comprises a reaction chamber (3). A substrate (31) is located in the reaction chamber (3), with a surface exposed to an environment (32) within the reaction chamber (3).

The system (7) comprises a first source (1), coupled to the reaction chamber (3) via a first valve (not shown). The first source (1) is for providing a vapor-phase composition in accordance with embodiments of the present invention. In the present example, the first source (1) comprises a carrier agent vessel (11) comprising a carrier agent comprising a group 13 halide, and a precursor vessel (12) comprising a chemical precursor comprising a metal halide compound. In the present example, an outlet of the carrier agent vessel (11) is fluidically coupled to an inlet of the precursor vessel (12). An outlet of the precursor vessel (12) is coupled, via the first valve, to the reaction chamber (3).

The system (7) comprises a controller (4) configured to control a temperature and/or pressure of the carrier agent vessel (11) for vaporizing the group 13 halide in the carrier agent vessel (11). For example, an interior of the carrier agent vessel (11) in which the group 13 halide is stored, may be heated to a temperature above a volatilization temperature, under a pressure within said interior, of the group 13 halide.

In the present example, a carrier gas (10), such as N₂, He, or Ar, is introduced, through an inlet of the carrier agent vessel (11), into the carrier agent vessel (11), for inducing the carrier agent, comprising the group 13 halide in the vapor phase, to flow, through the outlet of the carrier agent vessel (11) and through the inlet of the precursor vessel (12), into the precursor vessel (12). The controller (4) may adapt a temperature and/or pressure of the precursor vessel (12) so that the group 13 halide remains, in the precursor vessel (12), in the vapor phase.

Instead of, or in addition to, using the carrier gas (10) for inducing said flow, flow may be induced by a pressure-difference induced flow, wherein the reaction chamber (32) (with the first valve open) is at a lower pressure than the first source (1), thereby inducing a flow of the carrier agent in the carrier agent vessel (11) to the precursor vessel (12) (and subsequently to the reaction chamber (32)).

The volatilization temperature, under a pressure in the precursor vessel (12), of the metal halide compound is above a temperature in the precursor vessel (12), so that the metal halide compound is present in the precursor vessel (12) in a condensed state. The group 13 halide may coordinate, in the precursor vessel (12), with the metal halide compound, to bring the metal halide compound, coordinated to the vapor-phase group 13 halide, into the vapor phase as well. As such, a vapor-phase composition is obtained comprising the group 13 halide and the metal halide compound.

When the first valve, fluidically coupling the first source (1) to the reaction chamber (3), is opened by the controller (4), the carrier gas (10) may induce a flow of the vapor-phase composition from the precursor vessel (12), through the outlet of the precursor vessel (12) and through the first valve (not shown) into the reaction chamber (3).

The vapor-phase composition thus has a flow path from the first source (1), more in particular, from the precursor vessel (12) of the first source (1), via tubing connecting an outlet of the precursor vessel (12) to an inlet of the reaction chamber (3), and via the first valve into the reaction chamber (3), more in particular, to the substrate (31). In the present example, the temperature along said substantially complete flow path is too low for the metal halide compound to remain in the vapor phase, i.e., is below a volatilization temperature, dependent on pressure, of the metal halide compound. However, the temperature along said substantially complete flow path is sufficiently high for the group 13 halide to remain in the vapor phase, i.e., is above a volatilization temperature, dependent on pressure, of the group 13 halide. Furthermore, the temperature along said substantially complete flow path is sufficiently high for the multinuclear complex comprising the group 13 halide coordinated to the metal halide compound to remain in the vapor phase.

Reference is made to FIG. 2. Therefore, the group 13 halide may effectively transport the metal halide compound from the precursor vessel (12) to the substrate (31) in the reaction chamber (32), to form a thin film on the substrate (31) comprising at least the metal of the metal halide compound.

In the present example, a substrate temperature of the substrate (31) is adapted by the controller (4) so that the multinuclear complex as a whole is deposited, by chemical adsorption, on a portion of the exposed surface of the substrate (31). After said deposition, the first valve may be closed by the controller (4). Said deposition results in the formation of a thin film (61) on said portion of the exposed surface of the substrate (31) comprising the chemically adsorbed multinuclear complex.

However, as described elsewhere in the description, the present invention is not limited thereto, and instead, first, condensation of the multinuclear complex may occur followed by a chemical reaction with the surface, or selective chemical adsorption of the metal halide compound on the surface may occur.

In the present example, the carrier agent is only present for transporting the metal halide compound to the substrate (31), but should not be incorporated into a material that is to be formed on the substrate (31). Therefore, in the present example, selective release of the chemically adsorbed group 13 halide from the thin film (61) is induced.

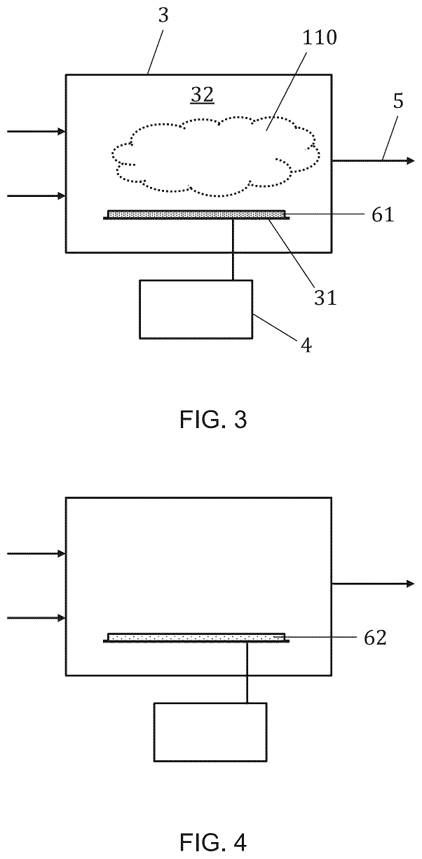

0 Reference is made to FIG. 3. For said selective release, the reaction chamber (3) may be purged of the group 13 halide (e.g., by vacuum pumping via an outlet (5) of the reaction chamber (3)). The substrate (31) may be heated by the heater controlled by the controller (4) to a temperature to a temperature at which bonds of the chemically adsorbed group 13 halide with the substrate (31), and with the metal halide compound, break. This may result in selective release of the chemically adsorbed group 13 halide (schematically indicated in FIG. 3 by the vapor (110) of the group 13 halide) from the thin film (61). Said released group 13 halide may be removed, e.g., by said purging.

Reference is made to FIG. 4. As a result, a thin film (62) containing the chemically adsorbed metal halide compound, substantially without the chemically adsorbed group 13 halide, may be formed.

With simultaneous reference to FIG. 1, subsequently, a second valve (not shown) may be opened by the controller (4), so that a co-reactant may be provided into the reaction chamber (3), from a co-reactant vessel (21) comprised in a second source (2), coupled to the reaction chamber (3) via the second valve. The co-reactant may, for example, be an oxygen precursor, a nitrogen precursor, or a reducing agent. The co-reactant may react with the chemically adsorbed metal halide compound of the thin film (62) on the substrate (31). Subsequently, the second valve may be closed, and the co-reactant may be purged from the reaction chamber (3).

This may be followed by a plurality of cycles comprising: opening the first valve to provide the vapor-phase composition into the reaction chamber (3); closing the first valve; purging; opening the second valve to provide the co-reactant into the reaction chamber; closing the second valve; and purging. Once a material of preferred dimensions and composition is formed on the substrate (31), said cycling may be terminated.

Although the present example provides a single controller (4) for performing different functions (including controlling valves, a temperature of the substrate (31), a temperature of the carrier agent vessel (11), a temperature of the precursor vessel (12), and a pressure within the reaction chamber (3)), the skilled person will realize that the different functions may be performed by different controllers, or some of the functions may be performed by a first controller while other functions may be performed by a second controller.

### Example: Precursor Vessel Comprising Multiple Chambers

Although in the above example, the first source comprises a carrier agent vessel for providing the group 13 halide and a precursor vessel for providing the metal halide compound, the invention is not limited to this specific configuration.

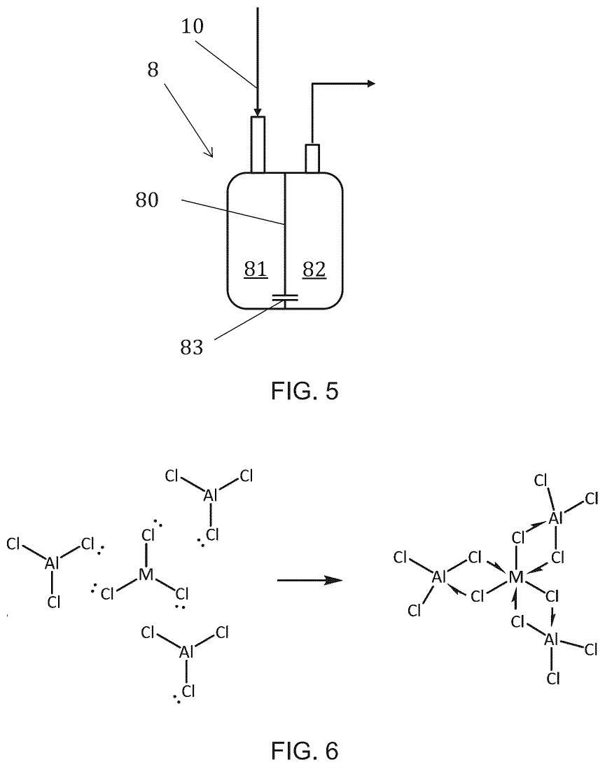

Reference is made to FIG. 5, which is a schematic representation of another example of a precursor vessel (8) in accordance with embodiments of the present invention. An interior volume of the precursor vessel (8) of this example comprises a first chamber (81), separated from a second chamber (82) by a wall (80). The wall (80) comprises a passage (83) that may comprise a valve (not shown). During storage, the valve may be closed, so that a group 13 halide in the first chamber (81) may be separated from a metal halide compound in the second chamber (82).

When the precursor vessel (8) is in use in a chemical deposition method, and the metal halide compound is to be provided in a reaction chamber for deposition, the valve separating the first chamber (81) from the second chamber (82) may be opened. The first chamber (81) may be heated so that the group 13 halide is in the vapor phase, and a carrier gas (10) may be introduced through an inlet into the first chamber (81) for inducing a flow of the group 13 halide through the passage (83) into the second chamber (82). The second chamber (82) may be heated as well to keep the group 13 halide in the vapor phase. The group 13 halide may bind to the metal halide compound to bring the metal halide compound into the vapor phase as well. Subsequently, the vapor phase composition comprising the metal halide compound bonded to the group 13 halide may be induced to flow through an outlet of the second chamber (82) towards the reaction chamber.

Although the present example is on a precursor vessel (8) comprising two chambers, the invention is not limited thereto, and the precursor vessel (8) may comprise more chambers, coupled to each other by valves. Still alternatively, the metal halide compound and the group 13 halide may be provided and/or stored together in a single chamber of the precursor vessel (8).

It is to be understood that although preferred embodiments, specific constructions and configurations, as well as materials, have been discussed herein for devices according to the present invention, various changes or modifications in form and detail may be made without departing from the scope of this invention. Functionality may be added or deleted from the block diagrams and operations may be interchanged among functional blocks. Steps may be added or deleted to methods described within the scope of the present invention.

1. A precursor vessel comprising:
a chemical precursor comprising a metal halide compound, and
a carrier agent for transporting said chemical precursor in a vapor phase, the carrier agent comprising a group 13 halide having, under a pressure within the precursor vessel, a volatilization temperature below a volatilization temperature of the metal halide compound,
wherein the precursor vessel is configured to supply a vapor comprising the chemical precursor and the carrier agent to a reaction chamber of a chemical vapor deposition system.

2. The precursor vessel of claim 1, wherein said metal halide compound has a volatilization temperature of at least 250° C., at least 300° C., at least 400° C., or at least 500° C., under said pressure.

3. The precursor vessel of claim 1, wherein the volatilization temperature of said group 13 halide is at least 20° C. lower than a volatilization temperature of said metal halide compound, under said pressure.

4. The precursor vessel of claim 1, wherein the metal halide compound is a metal halide, a metal nitride halide, or a metal oxohalide.

5. The precursor vessel of claim 4, wherein the metal halide compound comprises a metal selected from the group consisting of: a transition metal, a metal from the lanthanide series, and combinations thereof.

6. The precursor vessel of claim 4, wherein the metal halide compound comprises one or more halogen atoms selected from a list consisting of: fluorine, chlorine, bromine, iodine, and combinations thereof.

7. The precursor vessel of claim 6, wherein each of the one or more halogen atoms of the metal halide compound is chlorine.

8. The precursor vessel of claim 1, comprising the metal halide compound in a polymeric, non-crystalline, crystalline or liquid state.

9. The precursor vessel of claim 8, comprising the metal halide compound in a polymeric or crystalline state.

10. The precursor vessel of claim 1, wherein the group 13 element of the group 13 halide is selected from the group consisting of: boron, aluminum, gallium, and combinations thereof.

11. The precursor vessel of claim 10, wherein the group 13 element of the group 13 halide is aluminum.

12. The precursor vessel of claim 1, wherein the group 13 halide comprises one or more halogen atoms selected from the group consisting of: fluorine, chlorine, bromine, iodine, and combinations thereof.

13. The precursor vessel of claim 12, wherein each of the one or more halogen atoms of the group 13 halide is chlorine.

14. The precursor vessel of claim 1, wherein the halogen atoms of the group 13 halide are of a same type as the halogen atoms of the metal halide compound.

15. The precursor vessel of claim 1, wherein the metal halide compound and the group 13 halide form a multinuclear complex.

16. A method for chemical vapor depositing a material comprising a metal on a substrate, the method comprising:
providing the substrate in a reaction chamber, and then providing, from a first source, into the reaction chamber, a vapor-phase composition comprising a multinuclear complex comprising:
a chemical precursor comprising a halide compound of said metal, the metal halide compound having a volatilization temperature, under a pressure at a location along a flow path of the composition from the first source to the reaction chamber, above a temperature at said location, coordinated with
a carrier agent for transporting said metal halide compound in the vapor phase, the carrier agent comprising a group 13 halide having a volatilization temperature, under said pressure, below said temperature,
thereby forming a thin film comprising the metal on a portion of a surface of the substrate.

17. The method of claim 16, wherein the formed thin film comprises a chemically adsorbed multinuclear complex, wherein the method comprises a further step of:
inducing selective release of the group 13 halide from the thin film.

18. The method of claim 16, wherein said location comprises substantially the complete flow path of the composition.

19. A system for chemical vapor depositing a material comprising a metal, the system comprising:
a reaction chamber for receiving the substrate,
a first source, coupled to the reaction chamber via a first valve, for providing a vapor-phase composition comprising a multinuclear complex comprising:
a chemical precursor comprising a halide compound of the metal, coordinated with
a carrier agent for transporting said chemical precursor in the vapor phase, the carrier agent comprising a group 13 halide, and
a controller operably connected to the first valve, wherein the controller is configured and programmed to open the first valve to provide a flow of the composition into the reaction chamber and to close the first valve to cease the flow of the composition into the reaction chamber,
wherein the system is configured for, when said first valve is open, providing a temperature and a pressure at a location along a flow path of the composition from the first source to the reaction chamber, wherein a volatilization temperature, under said pressure, of the metal halide compound is above said temperature, and a volatilization temperature, under said pressure, of the group 13 halide is below said temperature.

20. A composition configured for depositing a thin film by chemical vapor deposition, preferably by atomic layer deposition, the composition comprising:
a chemical precursor comprising a metal halide compound, and
a carrier agent for transporting said chemical precursor in a vapor phase, the carrier agent comprising a group 13 halide and having, under a pressure within a range of from 10 to 1000 Pa, a volatilization temperature below a volatilization temperature of the metal halide compound.

21. A precursor vessel comprising:
a housing defining an interior volume of the precursor vessel, an inlet conduit seated in the housing and in fluid communication with the interior volume of the precursor vessel, the inlet conduit comprising at least one valve positioned thereon,
an outlet conduit seated in the housing and in fluid communication with the interior volume of the precursor vessel, the outlet conduit comprising at least one valve positioned thereon, and a metal halide compound impounded within the interior volume of the precursor vessel, wherein the metal halide compound comprises:
(i) a metal selected from the group consisting of cobalt, ruthenium, manganese, nickel, a group 3 metal, and a metal from the lanthanide series; and
(ii) one or more halogen atoms.

22. The precursor vessel of claim 21, wherein the precursor vessel further comprises a carrier agent comprising a group 13 halide having, under a pressure within the precursor vessel, a volatilization temperature below a volatilization temperature of the metal halide compound.
